(19) United States
(12) Patent Application Publication
(10) Pub. No.: US 2010/0213555 A1
(43) Pub. Date: Aug. 26, 2010

(54) METAL OXIDE SEMICONDUCTOR DEVICES HAVING CAPPING LAYERS AND METHODS FOR FABRICATING THE SAME

(75) Inventors: Michael HARGROVE, Clinton Corners, NY (US); Richard J. CARTER, Hopewell Junction, NY (US); Ying H. TSANG, Newburgh, NY (US); George KLUTH, Hopewell Junction, NY (US); Kisik CHOI, Hopewell Junction, NY (US)

Correspondence Address: INGRASSIA FISHER & LORENZ, P.C. (AMD), 7010 E. COCHISE ROAD, SCOTTSDALE, AZ, 85253, US

(73) Assignee: ADVANCED MICRO DEVICES, INC., Austin, TX (US)

(21) Appl. No.: 12/390,902

(22) Filed: Feb. 23, 2009

(51) Int. Cl. H01L 29/78; H01L 21/28

(52) U.S. Cl. 257/411; 438/591; 257/E21.19; 257/E29.255

(57) ABSTRACT

Methods for forming a semiconductor device comprising a semiconductor substrate are provided. In accordance with an exemplary embodiment, a method comprises forming a silicon oxide layer overlying the semiconductor substrate, forming a metal oxide gate capping layer overlying the silicon oxide layer, depositing a first metal gate electrode layer overlying the metal oxide gate capping layer, and removing a portion of the first metal gate electrode layer and the metal oxide gate capping layer to form a gate stack.

### FIELD OF THE INVENTION

The present invention generally relates to semiconductor devices and methods for fabricating semiconductor devices, and more particularly relates to metal oxide semiconductor devices having capping layers and methods for fabricating such metal oxide semiconductor devices.

### BACKGROUND OF THE INVENTION

The majority of present day integrated circuits (ICs) are implemented by using a plurality of interconnected field effect transistors (FETs), also called metal oxide semiconductor field effect transistors (MOSFETs or MOS transistors). The ICs are usually formed using both P-channel and N-channel FETs and the IC is then referred to as a complementary MOS or CMOS IC. MOS transistors typically comprise a gate insulator overlying a semiconductor substrate with a conductive gate electrode disposed overlying the gate insulator and between spaced-apart source and drain regions within the semiconductor substrate. A control voltage applied to the gate electrode controls the flow of current through a channel underlying the gate electrode and between the source and drain regions.

For decades, silicon oxides such as silicon dioxide (SiO₂) and silicon oxynitride (SiON) have been used as gate insulators because the level of insulation they provide has been adequate to meet IC industry design rules over that time. However, there is a continuing trend to incorporate more and more circuitry on a single IC chip. To accommodate this trend, the size of each individual device in the circuit and the spacing between device elements, or the pitch, is reduced for each new technology generation. As critical dimensions shrink, device components such as gate length and gate insulator thickness are scaled down in substantial proportion. At the 65 nm node technology, leakage current of devices fabricated with silicon dioxide insulators at the specified thickness begins to reach unacceptably high levels. Further, when polycrystalline silicon, or “polysilicon,” gates are used, the poly-depletion effect further degrades device performance by adding a small, but for advanced devices, an increasingly significant parasitic capacitance to each transistor.

Metal gates have been suggested as a means of solving this problem. High dielectric constant materials, also referred to as “high-k dielectrics,” and metal gate electrodes are under consideration for the 45 nm node technology and beyond to enable further scaling of devices. However, the metal-oxygen bonds typically contained within high-k materials generate low energy phonons when placed under an external electric field such as that used during the operation of a transistor. These phonons cause scattering of channel mobile charges resulting in a decrease in drive current.

To overcome this problem, silicon dioxide gate insulators have been suggested to replace the high-k dielectric gate insulators. However, when metals are used as gate electrodes in combination with SiO₂ gate insulators, such metals can compromise the insulating properties of the dielectric layer by becoming oxidized at the expense of reducing the oxide layer. Ideally, combining metal gate electrodes with SiO₂ gate insulator layers in a manner that inhibits oxide layer reduction could potentially extend the viability of silicon oxides as gate insulators, lessening the need for high-k materials along with their associated drawbacks.

Accordingly, it is desirable to provide semiconductor devices having capping layers interposed between a metal gate electrode and a silicon dioxide gate insulator layer. It is also desirable to provide methods for fabricating such semiconductor devices. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

In accordance with exemplary embodiments of the invention, methods for forming a semiconductor device comprising a semiconductor substrate are provided. One exemplary method comprises forming a silicon oxide layer overlying the semiconductor substrate, forming a metal oxide gate capping layer overlying the silicon oxide layer, depositing a first metal gate electrode layer overlying the metal oxide gate capping layer, and removing a portion of the first metal gate electrode layer and the metal oxide gate capping layer to form a gate stack.

A method for fabricating a semiconductor device on a semiconductor substrate having a first region and a second region in accordance with another exemplary embodiment of the invention is provided. The method comprises forming a silicon oxide layer overlying the first and second regions of the semiconductor substrate, forming a first metal oxide gate capping layer overlying a portion of the silicon oxide layer within the first region, forming a second metal oxide gate capping layer overlying a portion of the silicon oxide layer within the second region; forming a first metal gate electrode layer overlying the first metal oxide gate capping layer; and forming a second metal gate electrode layer overlying the second metal oxide gate capping layer.

A semiconductor device in accordance with an exemplary embodiment of the invention is provided. The device has a first gate stack overlying a semiconductor substrate. The first gate stack comprises a first silicon oxide insulator disposed overlying the semiconductor substrate, a first metal oxide capping layer disposed overlying the first silicon oxide insulator, and a first metal gate electrode layer disposed overlying the first metal oxide capping layer.

### BRIEF DESCRIPTION OF THE DRAWINGS

The present invention will hereinafter be described in conjunction with the following drawing figures, wherein like numerals denote like elements, and wherein:

FIGS. 1-3 illustrate schematically, in cross-section, methods for fabricating a semiconductor device having a metal oxide capping layer in accordance with an exemplary embodiment of the present invention;

FIGS. 4-7 illustrate schematically, in cross-section, methods for fabricating a semiconductor device having transistors with metal oxide capping layers comprised of like composition in conjunction with metal gate electrodes of like composition in accordance with another exemplary embodiment of the present invention;

FIGS. 8-14 in conjunction with FIGS. 4-5 illustrate schematically, in cross-section, methods for fabricating a semiconductor device having transistors with metal oxide capping layers comprising different composition in conjunction with metal gate electrodes of like composition in accordance with another exemplary embodiment of the present invention;

FIGS. 15-19 in conjunction with FIGS. 4-5 illustrate schematically, in cross-section, methods for fabricating a semiconductor device having transistors with metal oxide capping layers comprising like composition in conjunction with metal gate electrodes of different composition in accordance with another exemplary embodiment of the present invention; and

FIGS. 20-23 in conjunction with FIGS. 4-5 and 8-11 illustrate schematically, in cross-section, methods for fabricating a semiconductor device having transistors with metal oxide capping layers comprising different composition in conjunction with metal gate electrodes of different composition in accordance with another exemplary embodiment of the present invention.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

The various embodiments of the present invention describe methods for fabricating an MOS transistor having enhanced electrical insulation between a metal gate electrode and the underlying channel region. These methods include the insertion of a metal oxide capping layer interposed between the metal gate electrode and a silicon oxide gate insulator. The capping layer improves the stability of the interface between the electrode and the insulator layer by inhibiting oxidation/reduction reactions that may otherwise occur between the gate metal and the oxide insulator. Accordingly, the capping layer enables conventional silicon oxide gate insulators to be used compatibly with metal gate electrodes in high performance devices especially for the 45 nm technology node and beyond.

FIGS. 1-3 illustrate schematically, in cross section, a method for forming an MOS transistor 100 in accordance with an exemplary embodiment of the invention. The embodiments herein described apply to N-channel MOS (NMOS) and to P-channel MOS (PMOS) transistors. While the fabrication of one MOS transistor is illustrated in FIGS. 1-3, it will be appreciated that the methods depicted can be used to fabricate any number of such transistors. Various steps in the manufacture of MOS components are well known and so, in the interest of brevity, many conventional steps will only be mentioned briefly herein or will be omitted entirely without providing the well known process details.

Referring to FIG. 1, the method begins by forming a gate insulator layer 112 overlying a semiconductor substrate 110. The semiconductor substrate can be silicon, germanium, a III-V material such as gallium arsenide, or other semiconductor material. Semiconductor substrate 110 will hereinafter be referred to for convenience, but without limitation, as a silicon substrate. The term “silicon substrate” is used herein to encompass the relatively pure silicon materials typically used in the semiconductor industry as well as silicon admixed with other elements such as germanium, carbon, and the like. The silicon substrate may be a bulk silicon wafer or, as illustrated, may be a thin layer of silicon 106 on an insulating layer 104 (commonly know as silicon-on-insulator, or SOI) that, in turn, is supported by a carrier wafer 102. At least a surface region 108 of silicon substrate 110 is impurity doped, for example by forming N-type well regions and P-type well regions for the fabrication of P-channel (PMOS) transistors and N-channel (NMOS) transistors, respectively.

Typically, gate insulating layer 112 can be a layer of thermally grown silicon dioxide in cases wherein semiconductor substrate 110 is either a bulk silicon or an SOI wafer (as illustrated), or alternatively, and for other types of semiconductor substrates, a deposited insulator of a silicon oxide. As used herein, the term silicon oxide is taken to include silicon oxynitride as well. Oxide gate insulator layers can be deposited, for example, by chemical vapor deposition (CVD), low pressure chemical vapor deposition (LPCVD), or plasma enhanced chemical vapor deposition (PECVD). Gate insulator layer 112 is preferably formed using a thermal oxidation process and has a thickness in a range of from about 0.8 nm to about 1.3 nm, and is preferably about 1 nm thick.

In the next step, a capping material layer 114 comprising metal oxide is formed overlying gate insulator layer 112. As used herein, the term metal oxide includes both metal oxides and metal oxynitrides. Capping material layer 114 may comprise any one or a combination of metal oxides and/or metal oxynitrides including lanthanum oxides (LaOₓ) and lanthanum oxynitrides (LaOₓN_{y}), hafnium oxides (HfOₓ) and hafnium oxynitrides (HfOₓN_{y}), zirconium oxides (ZrOₓ) and zirconium oxynitrides (ZrOₓN_{y}), magnesium oxides (MgOₓ) and magnesium oxynitrides (MgOₓN_{y}), aluminum oxides (AlOₓ) and aluminum oxynitrides (AlOₓN_{y}), titanium oxides (TiOₓ) and titanium oxynitrides (TiOₓN_{y}), tantalum oxides (TaOₓ) and tantalum oxynitrides (TaOₓN_{y}), and yttrium oxides (YOₓ) and yttrium oxynitrides (YOₓN_{y}), where x and y are numbers greater than zero. Capping material layer 114 may be deposited using any suitable deposition technique such as, for example, physical vapor deposition (PVD) such as including evaporation or sputtering, CVD, PECVD, LPCVD, and atomic layer deposition (ALD). Preferably, capping material layer 114 is formed by ALD. Capping material layer 114 may also be formed as a self-assembling or self-assembled monolayer (SAM) using a chemical compound suitable for such deposition. Such a compound typically comprises a molecular structure suitably functionalized for adhesive attraction or bonding to molecular sites of a substrate surface, in this case preferably SiO₂, but lacking a propensity to form films that exceed monolayer thicknesses. For this application, a suitable SAM material includes, for example, a metal oxide or metal oxynitride-comprising molecular structure to provide a buffering effect that inhibits a subsequently formed metallic electrode from reducing the SiO₂ gate insulator. SAM compounds may be deposited via casting from a suitable solvent using, for example, a spin coating or dipping process. The thickness of capping material layer 114 is in a range of from about 0.1 nm to about 1 nm and is preferably about 0.2 nm to about 0.4 nm thick. When formed, preferably capping material layer 114 provides a uniform film, having a substantially monolayer structure, overlying gate insulator layer 112.

Next, a metal-comprising gate layer 116 is formed overlying capping material layer 114. The metal-comprising layer may be formed of lanthanum (La) or lanthanum alloys, aluminum (Al) or aluminum alloys, magnesium (Mg) or magnesium alloys, titanium-based materials such as titanium nitride (TiN) or titanium aluminum nitride (TiAlN), tantalum-based materials such as tantalum nitride (TaN), tantalum aluminum nitride (TaAlN), or tantalum carbide (Ta₂C), tungsten nitride (WN), or the like, and is preferably TiN. Metal-comprising gate layer 116 preferably has a thickness of from about 0.5 nm to about 10 nm, and is preferably about 5 nm thick. A thin layer of oxide (not shown) may form on metal-comprising gate layer 116, such as from exposure to an ambient environment or by other intentional oxidation.

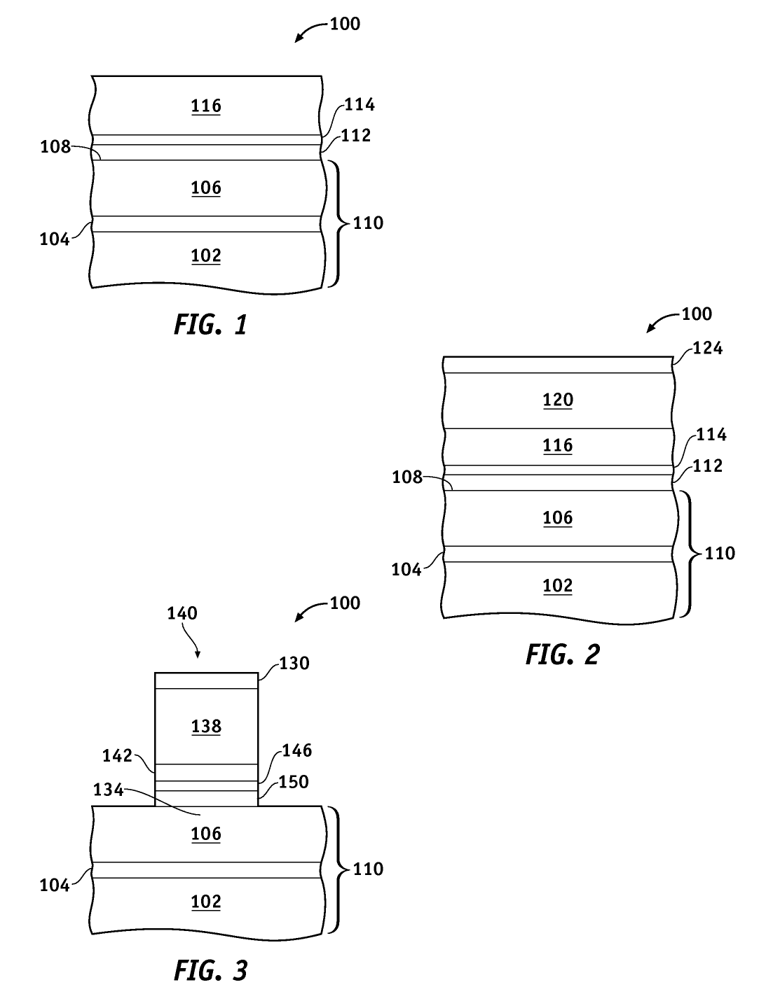

Referring to FIG. 2, in one exemplary embodiment, a polysilicon gate layer 120 is deposited overlying metal-comprising gate layer 116. Polysilicon gate layer 120 is preferably deposited as undoped polycrystalline silicon and is subsequently impurity doped by ion implantation. Polysilicon gate layer 120 can be deposited by LPCVD by the hydrogen reduction of silane.

A hard mask layer 124 comprising, for example, silicon oxide, silicon nitride (Si₃N₄), or titanium nitride (TiN) may be deposited overlying metal-comprising gate layer 116 and polysilicon gate layer 120, if present, using, for example, an LPCVD process. Hard mask layer 124 used as a hard mask for the etching of polysilicon gate layer 120, metal-comprising gate layer 116, capping material layer 114, and gate insulator layer 112, and thus may be deposited to a thickness suitable for this purpose in consideration of the selectivity of each etch process. In one embodiment, hard mask layer 124 comprises Si₃N₄, and has a thickness in a range of from about 2 nm to about 10 nm.

Referring to FIG. 3, hard mask layer 124 is patterned using a photolithography and etch sequence to form a hard mask 130, and the underlying layers including polysilicon layer gate 120, metal-comprising gate layer 116, capping material layer 114, and gate insulator layer 112 are each anisotropically etched to form a gate stack 140 overlying a channel region 134 disposed within thin silicon layer 106. Etching processes are performed using patterned photoresist (not shown) and/or hard mask 130 as etch masks. Polysilicon gate layer 120 can be etched using, for example, reactive ion etching (RIE) using a Cl⁻ or Cl₂/HBr/O₂ chemistry. Hard mask layer 124 and gate insulator layer 112 can be etched, for example, by RIE in a CHF₃, CF₄, or SF₆ chemistry. Metal-comprising gate layer 116 and capping material layer 114 may be etched by RIE using, for example, a Cl₂/HBr chemistry for TiN, a Cl₂/CF₄ chemistry for TaN, or a SF₆/CH₂F₂ chemistry for WN. When etching of these layers is completed, gate stack 140 comprises a metal gate electrode 142, a metal oxide capping layer 146, a silicon dioxide gate insulator 150, and an optional overlying polysilicon gate electrode 138. The metal oxide capping layer 146, being interposed between metal gate electrode 142 and silicon dioxide gate insulator 150, prevents or at least minimizes oxidation of the metal gate electrode and thereby prevents or at least minimizes reduction reactions at or within the silicon dioxide insulator. Fabrication of a MOS transistor 100 may continue in the conventional manner with, for example, the implanting of dopant ions into the thin silicon layer 106 to form source and drain extensions and the fabrication of one or more spacers, followed by an additional implanting of dopant ions into thin silicon layer 106 to form source and drain regions.

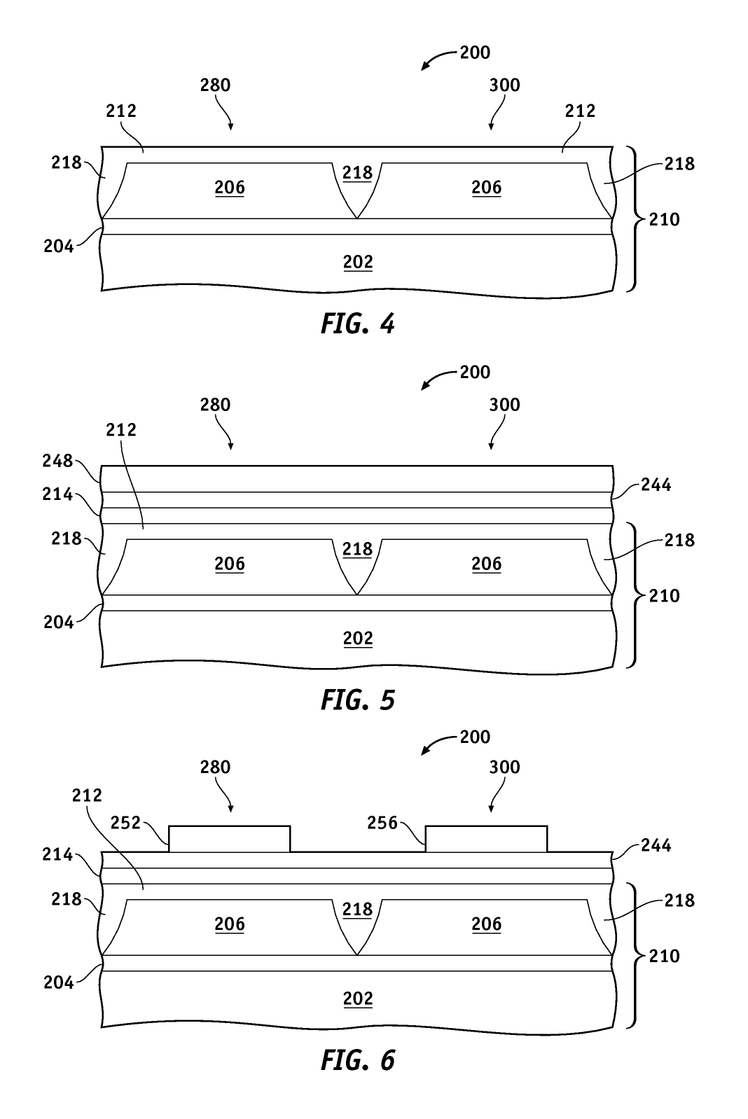

FIGS. 4-23 illustrate schematically, in cross section, methods for forming a semiconductor device 200 having two transistors, each transistor with a gate stack having, relative to the other gate stack, a metal oxide capping layer of the same or of different composition, and a metal gate electrode of the same or of different composition in accordance with other exemplary embodiments of the invention. These process schemes may be used for certain applications such as when it is desirable to produce semiconductor devices having varying threshold voltages (Vₜ). While the fabrication of only two transistors is illustrated in FIGS. 4-23, it will be appreciated that any suitable number of MOS transistors can be formed. Many of the elements and processing steps used for this embodiment have been previously described and so, in the interest of brevity, these steps will be discussed only briefly.

In a first exemplary embodiment illustrated in FIGS. 4-7, a gate stack is formed overlying each of two differently doped regions, each stack having, relative to the other stack, a metal oxide gate capping layer of the same composition, and a metal gate electrode of the same composition. The method begins as illustrated in FIG. 4 by providing a semiconductor substrate, which can be a bulk substrate or, as illustrated, an SOI silicon substrate 210 having an insulating layer 204 interposed between an overlying thin silicon layer 206, and an underlying silicon carrier substrate 202. Shallow trench isolation (STI) regions 218 comprising silicon oxide are formed within SOI substrate 210 using well known lithographic, etch, deposition, and chemical mechanical planarization (CMP) processes, and are used to electrically isolate subsequently formed transistors. After formation of STI regions 218, SOI substrate 210 has regions 280 and 300 that are subsequently impurity doped, for example, such that one region comprises an N-type well region and the other region comprises a P-well region. Preferably a silicon dioxide gate insulator layer 212 is formed overlying thin silicon layer 206 using a thermal oxidation process. Alternatively, a silicon oxide or SiON layer may be deposited, as described previously, by other methods including CVD or PECVD. Gate insulator layer 212 has a thickness in a range of from about 0.8 nm to about 1.3 nm, and is preferably about 1 nm thick.

Following the formation of gate insulator layer 212, the method continues with the formation of a metal oxide gate capping layer 214 overlying gate insulator layer 212 in each of regions 280 and 300, as illustrated in FIG. 5. Metal oxide gate capping layer 214 may comprise any one or a combination of the following metal oxide materials, including metal oxynitride materials, such as LaOₓ and LaOₓN_{y}, HfOₓ and HfOₓN_{y}, ZrOₓ and ZrOₓN_{y}, MgOₓ and MgOₓN_{y}, AlOₓ and AlOₓN_{y}, TiOₓ and TiOₓN_{y}, TaOₓ and TaOₓN_{y}, and YOₓ and YOₓN_{y}, where x and y are greater than zero. Metal oxide gate capping layer 214 may be formed using PVD, CVD, ALD, or by self-assembly of a SAM, to a thickness in a range of from about 0.1 nm to about 1 nm, and is preferably about 0.2 nm to about 0.4 nm thick.

Next, a metal gate layer 244 is blanket-deposited overlying metal oxide gate capping layer 214. Metal gate layer 244 may be deposited using any suitable metal deposition process such as a PVD process, and has a thickness in a range of from about 0.5 nm to about 10 nm, and is preferably about 5 nm thick. Metal gate layer 244 may be formed of La or lanthanum alloys, Al or aluminum alloys, Mg or magnesium alloys, titanium-based materials such as TiN or TiAlN, tantalum-based materials such as TaN, TaAlN, or Ta₂C, or WN, or the like, or combinations thereof, and preferably comprises TiN.

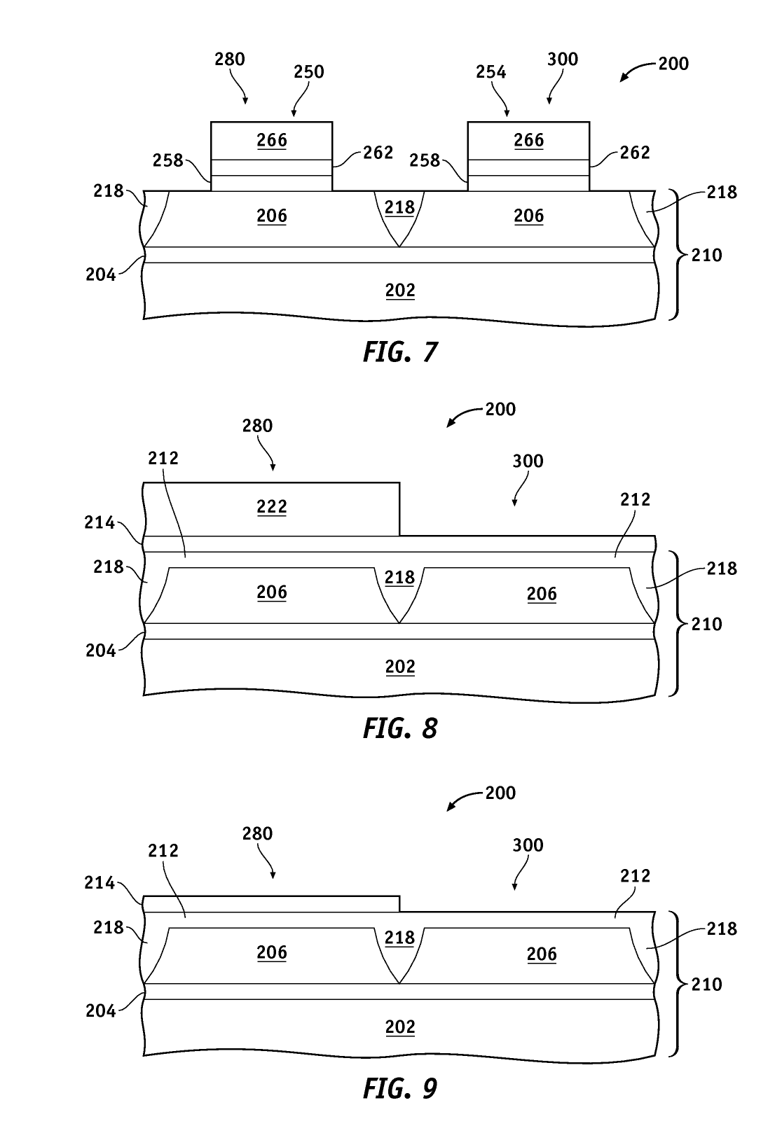

A hard mask layer 248 having a composition and thickness suitable for use as a hard etch mask is blanket-deposited overlying metal gate layer 244. Exemplary materials that may be used for hard mask layer 248 include SiO₂, TiN, and preferably Si₃N₄. Hard mask layer 248 is patterned using a lithographic and dry etch process sequence to form hard masks 252 and 256 overlying regions 280 and 300, respectively, as illustrated in FIG. 6. Hard masks 252 and 256 are subsequently used as hard etch masks for etching gate insulator layer 212, metal oxide gate capping layer 214, and metal gate layer 244. Hard masks 252 and 256 are then removed. Following such etching and removal, a gate stack 250 is formed overlying region 280 comprising a gate insulator 258, a metal oxide gate cap 262, and a metal gate electrode 266, as illustrated in FIG. 7. Similarly, a gate stack 254 is formed overlying region 300 comprising a gate insulator 258, a metal oxide gate cap 262, and a metal gate electrode 266. Although not illustrated, a layer of polycrystalline silicon can be deposited overlying metal gate layer 244 prior to the deposition of hard mask layer 248 and patterned in a manner described above using hard masks 252 and 256 as etch masks to form a polycrystalline gate electrode. Gate stacks 250 and 254 each have, relative to the other stack, metal oxide gate caps of like composition and metal gate electrodes of like composition.

In another exemplary embodiment illustrated in FIGS. 8-14, a gate stack is formed in each of regions 280 and 300, each stack having, relative to the other stack, a metal oxide gate capping layer of differing composition, and a metal gate electrode of like composition. This method begins with the formation of a gate insulator layer 212 and metal oxide gate capping layer 214, as illustrated in FIGS. 4-5, and previously described. Following the deposition of metal oxide gate capping layer 214, the method continues with the formation of a patterned photoresist mask 222 overlying region 280 using any suitable photolithography process, as illustrated in FIG. 8. Metal oxide gate capping layer 214 then is removed from region 300, as illustrated in FIG. 9, using a suitable wet or dry etch process that is highly selective to silicon dioxide (or SiON) so as not to erode gate insulator layer 212. Photoresist mask 222 then is removed.

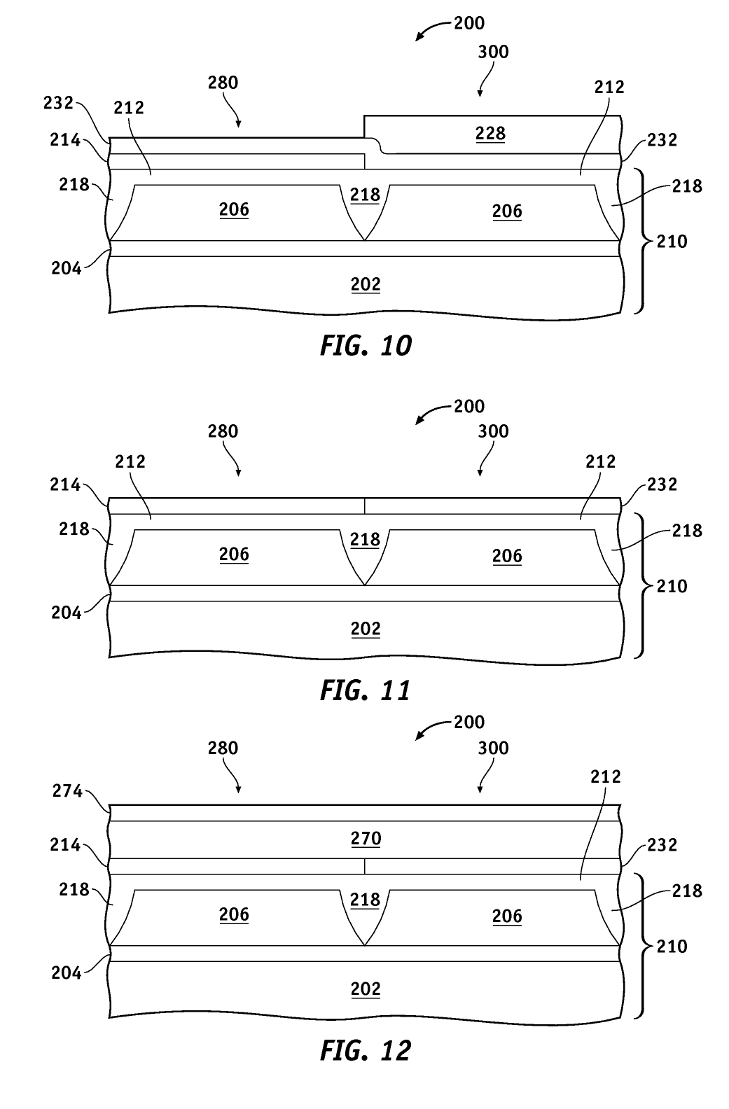

The method continues with the deposition of a metal oxide gate capping layer 232 overlying regions 280 and 300, as shown in FIG. 10. Metal oxide gate capping layer 232 may comprise any one or a combination of the metal oxide and metal oxynitride materials previously described for metal oxide gate capping layer 214, but has a different composition than that chosen for layer 214. Metal oxide gate capping layer 232 may be deposited using any of the deposition methods discussed above for metal oxide gate capping layer 214, and has a thickness in a range of from about 0.1 nm to about 1 nm, and is preferably about 0.2 nm to about 0.4 nm thick. Next, a patterned photoresist mask 228 is formed overlying metal oxide gate capping layer 232 in region 300 using a suitable photolithography process. As depicted in FIG. 11, metal oxide gate capping layer 232 is removed from the unmasked region 280 using a suitable wet or dry etch process highly selective to metal oxide gate capping layer 214. Photoresist mask 228 then is removed.

Next, a metal gate layer 270 is blanket-deposited overlying metal oxide gate capping layers 214 and 232, as illustrated in FIG. 12. Metal gate layer 270 may be deposited using any of the deposition processes previously described for metal gate layer 244, and may comprise any one or a combination of the metals described above for metal gate layer 244. Metal gate layer 270 has a thickness in a range of from about 0.5 nm to about 10 nm, and is preferably about 5 nm thick.

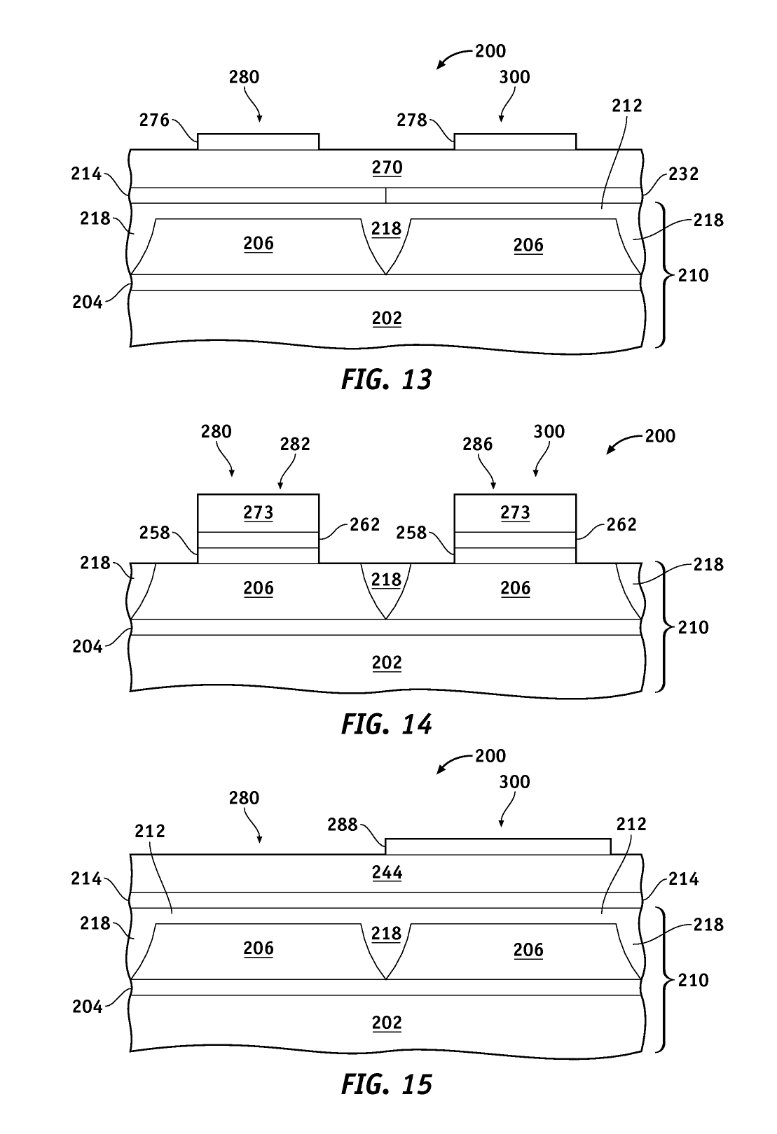

A hard mask layer 274 then is blanket-deposited overlying metal gate layer 270. Hard mask layer 274 has a suitable thickness and composition described above for use as an etch mask for each of the layers overlying regions 280 and 300. Hard mask layer 274 is patterned using a lithography and etch process sequence to form hard masks 276 and 278 overlying regions 280 and 300, respectively, as illustrated in FIG. 13. Hard masks 276 and 278 are subsequently used to etch gate insulator layer 212, metal oxide gate capping layers 214 and 232, and metal gate layer 270, to form gate stacks 282 and 286 overlying regions 280 and 300, respectively, as illustrated in FIG. 14. Hard masks 276 and 278 are then removed. Referring to FIG. 14, following these etches and removal, gate stack 282 includes a gate insulator 258, a metal oxide gate cap 262, and a metal gate electrode 273. Gate stack 286 includes a gate insulator 258, a metal oxide gate cap 277, and a metal gate electrode 273. As described above, a polycrystalline gate electrode (not illustrated) can be included in each of gate stacks 282 and 286 by depositing and patterning a polycrystalline silicon layer overlying metal gate layer 270. Gate stacks 282 and 286 each have, relative to the other stack, metal oxide gate caps of different composition, and metal gate electrodes of like composition.

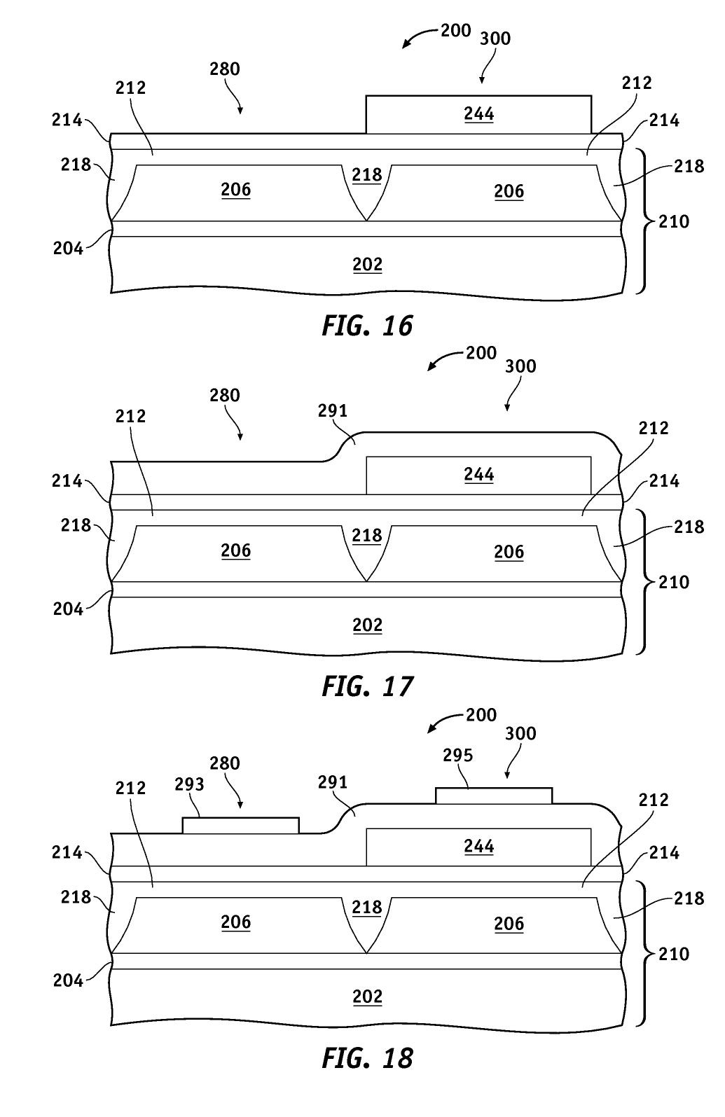

In a further embodiment illustrated in FIGS. 15-19, a gate stack is formed overlying each of regions 280 and 300, each stack having, relative to the other stack, a metal oxide gate capping layer of the same composition, and a metal gate electrode of different composition. This method begins with the formation of gate insulator layer 212, metal oxide gate capping layer 214 and metal gate layer 244, as illustrated in FIGS. 4-5, and previously described. Following the deposition of metal gate layer 244, the method continues with the formation of a patterned hard mask layer 288 overlying metal gate layer 244, as illustrated in FIG. 15. Hard mask 288 then is used as a mask for etching metal gate layer 244 in region 280, as illustrated in FIG. 16. This etch process is performed selectively so as not to erode metal oxide gate capping layer 214. The etch chemistry used will depend, in part, on the material composition of metal gate layer 244 to be etched, and may be, for example, a Cl₂/HBr chemistry for TiN, a Cl₂/CF₄ chemistry for TaN, or a SF₆/CH₂F₂ chemistry for WN. Hard mask 288 is then removed. Alternatively, etch masking for metal gate layer 244 may be performed using a soft photoresist mask alone (not shown) without the benefit of a hard mask layer provided selectivity of the etch process used is sufficient to remove metal gate layer 244 from region 280 without complete consumption of the photoresist mask.

A metal gate layer 291 comprising a different composition than that of metal gate layer 244 then is blanket-deposited overlying regions 280 and 300 including metal gate layer 244, as illustrated in FIG. 17. Metal gate layer 291 may be formed of, and deposited by, any of the suitable materials and deposition processes previously described for metal gate electrode layer 244. Metal gate layer 291 has a thickness in a range of from about 0.5 nm to about 10 nm, and is preferably about 5 nm thick.

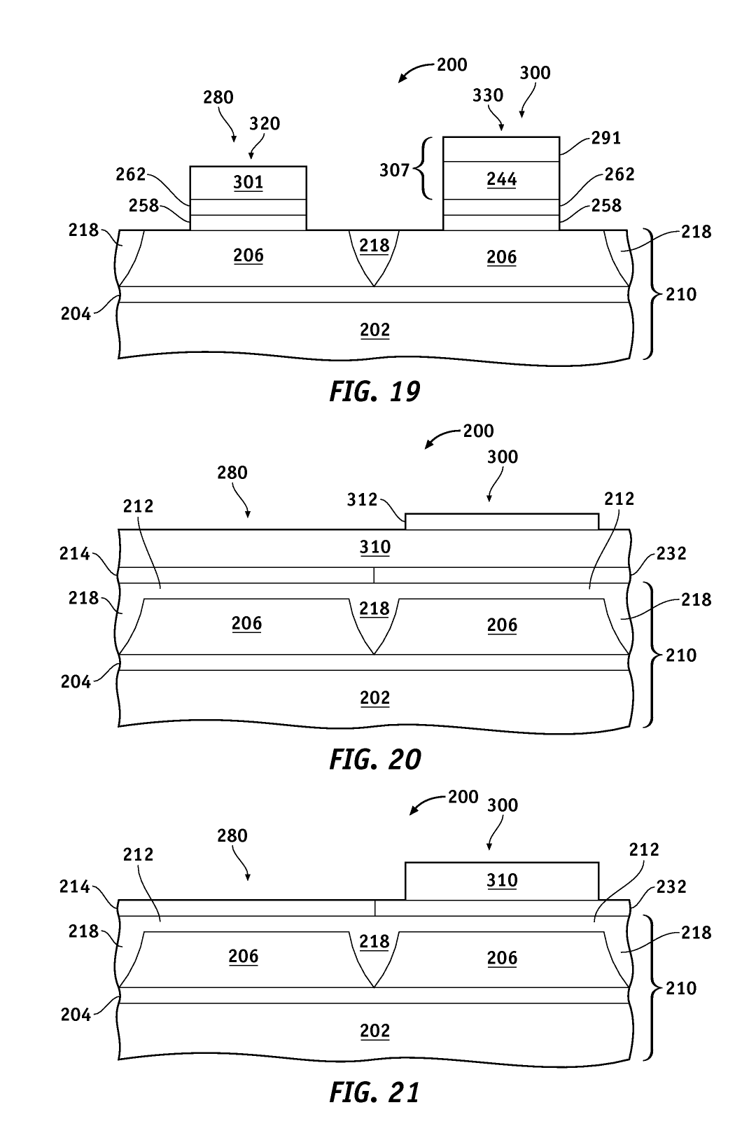

Following the deposition of metal gate layer 291, additional layers may be formed depending upon the intended application of device 200 and the overall process used. These layers include a blanket-deposited hard mask layer (not shown), that is deposited overlying metal gate layer 291. The hard mask layer comprises a composition and thickness suitable as a hard mask used to etch each of the layers overlying thin silicon layer 206 in regions 280 and 300, including metal gate layer 244 and 291 in region 300. Exemplary materials that may be used for hard mask layer 296 include TiN, and preferably also include Si₃N₄ and SiO₂. The hard mask layer then is patterned using lithography and etch processes as previously described to form hard masks 293 and 295 in regions 280 and 300, respectively, as illustrated in FIG. 18. Hard masks 293 and 295 are subsequently used as masks for etching oxide gate insulator layer 212, metal oxide gate capping layer 214, and metal gate layers 244 and 291. Hard masks 293 and 295 are then removed. Referring to FIG. 19, following such etches and removal, a gate stack 320 is formed overlying region 280 and includes a gate insulator 258, a metal oxide gate cap 262, and a metal gate electrode 301, comprising metal gate layer 291. Similarly, a gate stack 330 is formed overlying region 300 and includes a gate insulator 258, a metal oxide gate cap 262, and a metal gate electrode 307 comprising metal gate layers 244 and 291. As described above, a polycrystalline gate electrode (not illustrated) can be included in each of gate stacks 320 and 330 by depositing and patterning a polycrystalline silicon layer overlying metal gate layer 291. Gate stacks 320 and 330 each have, relative to the other stack, metal oxide gate caps of like composition and metal gate electrodes of different composition.

In yet a further embodiment illustrated in FIGS. 20-23, a gate stack is formed overlying each of regions 280 and 300, each stack having, relative to the other stack, a metal oxide gate capping layer of different composition, and a metal gate electrode of different composition. This embodiment may be used to enhance overall device performance such as, for example, when it is desirable to set the threshold voltages for each device type at different levels. This method begins with steps that have been previously described and are illustrated in FIGS. 4-5, and 8-11. Following the removal of photoresist mask 228, as illustrated in FIG. 11, a metal gate layer 310 is blanket-deposited overlying metal oxide gate capping layers 214 and 232, as illustrated in FIG. 20. Metal gate layer 310 may be deposited using any suitable metal deposition process and may comprise any of the materials previously described for metal gate layer 244, and preferably comprises TiN. Next a hard mask layer (not shown) is deposited overlying metal gate layer 310. The hard mask layer may comprise any material suitable as a hard etch mask for metal gate layer 310 including SiOₓ, and preferably Si₃N₄. The hard mask layer is then patterned using a lithography and dry etch process sequence to form a hard mask 312.

Next, hard mask layer 312 is used as an etch mask in conjunction with an RIE process to remove metal gate layer 310 in region 280, as illustrated in FIG. 21. The etch process is performed selectively so as not to erode metal oxide gate capping layers 214 and 232. The etch chemistry used for etching the metal gate layers will depend upon the composition of metal gate layer 310, and has been previously described. A photoresist mask (not shown) may be used as a substitute for a patterned hard etch mask provided the process selectivity for etching metal gate layer 310 is sufficient.

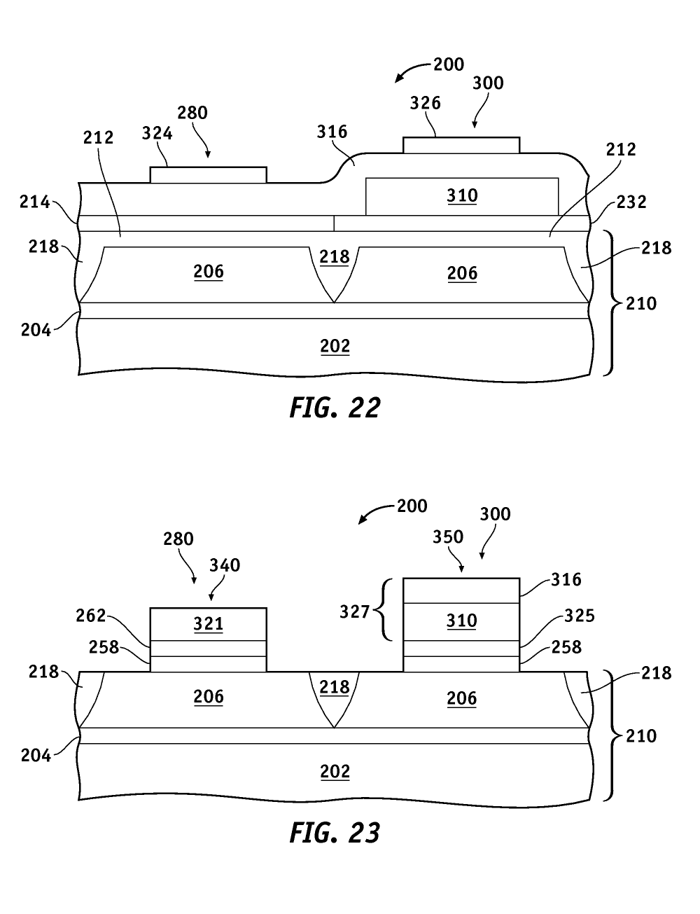

A metal gate layer 316 comprising a composition different from that of metal gate layer 310 then is blanket-deposited overlying regions 280 and 300 including metal gate layer 310, as illustrated in FIG. 22. Metal gate layer 316 may be deposited using any of the suitable metal deposition methods and may comprise any of the materials or combinations of materials previously described for metal gate layer 244, and preferably comprises La. Metal gate layer 316 has a thickness in a range of from about 0.5 nm to about 10 nm, and is preferably about 5 nm thick. Following the deposition of metal gate layer 316, additional overlying layers may be formed depending upon the overall process used. These layers comprise a blanket-deposited hard mask layer (not shown), deposited overlying metal gate layer 316, and comprising a composition and thickness suitable for use as a hard etch mask such as Si₃N₄, SiO₂, or TiN.

The hard mask layer then is patterned using a photolithographic and RIE process sequence to form hard masks 324 and 326, respectively, as illustrated in FIG. 22. Hard masks 324 and 326 are then used as etch masks for the etching of oxide gate insulator layer 212, metal oxide gate capping layers 214 and 232, and metal gate layers 310 and 316. Hard masks 324 and 326 are then removed. Referring to FIG. 23, when these etches and removals are complete, a gate stack 340 is formed overlying region 280 and includes a gate insulator 258, a metal oxide gate cap 262, and a metal gate electrode 321 comprising metal gate layer 316. A gate stack 350 is also formed overlying region 300 and includes a gate insulator 258, a metal oxide gate cap 325, and a metal gate electrode 327 comprising metal gate layers 310 and 316. As described above, a polycrystalline gate electrode can be included in gate stacks 340 and 350 by depositing and patterning a polycrystalline silicon layer overlying metal gate layer 316. Gate stacks 340 and 350 each have, relative to the other stack, metal oxide gate caps of different composition and metal gate electrodes of different composition.

Accordingly, the embodiments described herein provide novel methods for incorporating a metal oxide or metal oxynitride gate capping layer between a silicon oxide or silicon oxynitride gate insulator and a metal gate electrode. The capping layer comprises a film, having a substantially monolayer thickness, of any one or a combination of several metal oxides and oxynitrides including: LaOₓ and LaOₓN_{y}, HfOₓ and HfOₓN_{y}, ZrOₓ and ZrOₓN_{y}, MgOₓ and MgOₓN_{y}, AlOₓ and AlOₓN_{y}, TiOₓ and TiOₓN_{y}, TaOₓ and TaOₓN_{y}, YOₓ and YOₓN_{y}. The capping layer enhances electrical isolation between the metal gate and the channel of a transistor by acting as a buffer layer that inhibits reduction of the SiO₂ or SiON gate insulator by the gate metal. Further, the capping layer enables performance enhancing metal gates to be used in conjunction with silicon oxide gate insulators, and thus eliminates many of the problems associated with using high-k dielectrics in this capacity. Furthermore, transistors of a semiconductor device may be fabricated with metal oxide or metal oxynitride capping layers having differing compositions by using conventional lithographic masking and etch processes. Accordingly, these methods may be used with both PMOS and NMOS devices and can be integrated into a conventional fabrication sequence to provide improved device performance.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method for forming a semiconductor device comprising a semiconductor substrate, wherein the method comprises the steps of:
forming a silicon oxide layer overlying the semiconductor substrate;
forming a metal oxide gate capping layer overlying the silicon oxide layer;
depositing a first metal gate electrode layer overlying the metal oxide gate capping layer; and
removing a portion of the first metal gate electrode layer, and the metal oxide gate capping layer to form a gate stack.

2. The method of claim 1, wherein the step of forming a metal oxide gate capping layer comprises forming a metal oxide gate capping layer using PVD, CVD, ALD, or by self-assembly of a self-assembling monolayer.

3. The method of claim 1, wherein the step of forming a metal oxide gate capping layer comprises forming a metal oxide gate capping layer comprising a material selected from a group consisting of lanthanum oxides and oxynitrides, hafnium oxides and oxynitrides, zirconium oxides and oxynitrides, magnesium oxides and oxynitrides, aluminum oxides and oxynitrides, titanium oxides and oxynitrides, tantalum oxides and oxynitrides, yttrium oxides and oxynitrides, and a combination thereof.

4. The method of claim 1, wherein the step of forming a silicon oxide layer comprises forming a silicon oxide layer having a thickness in a range of from about 0.8 nm to about 1.3 nm.

5. The method of claim 1, wherein the step of forming a metal oxide gate capping layer comprises forming a metal oxide gate capping layer having a thickness in a range of from about 0.1 nm to about 1 nm.

6. The method of claim 5, wherein the step of forming a metal oxide gate capping layer comprises forming a metal oxide gate capping layer having a thickness in a range of from about 0.2 nm to about 0.4 nm.

7. The method of claim 1, wherein the step of depositing a first metal gate electrode layer comprises depositing a first metal gate electrode layer comprising a material selected from a group consisting of lanthanum (La) and lanthanum alloys, aluminum (Al) and aluminum alloys, magnesium (Mg) and magnesium alloys, titanium-based materials, tantalum-based materials, and tungsten nitride (WN).

8. The method of claim 1, further comprising the step of depositing a second metal gate electrode layer overlying the first metal gate electrode layer having a composition different from that of the first metal gate electrode layer, wherein the step of removing further comprises removing a portion of the second metal gate electrode layer to form the gate stack.

9. The method of claim 1, further comprising the step of forming a polycrystalline silicon layer overlying the first metal gate electrode layer, wherein the step of removing further comprises removing a portion of the polycrystalline silicon layer to form the gate stack.

10. A method of fabricating a semiconductor device on a semiconductor substrate having a first region and a second region, the method comprising the steps of:
forming a silicon oxide layer overlying the first and second regions of the semiconductor substrate;
forming a first metal oxide gate capping layer overlying a portion of the silicon oxide layer within the first region;
forming a second metal oxide gate capping layer overlying a portion of the silicon oxide layer within the second region;
forming a first metal gate electrode layer overlying the first metal oxide gate capping layer; and
forming a second metal gate electrode layer overlying the second metal oxide gate capping layer.

11. The method of claim 10, wherein the step of forming a first metal oxide gate capping layer comprises forming a first metal oxide gate capping layer using PVD, CVD, ALD, or via self-assembly of a self-assembling monolayer.

12. The method of claim 10, wherein the step of forming a first metal oxide gate capping layer comprises forming a first metal oxide gate capping layer comprising a material selected from a group consisting of lanthanum oxides and oxynitrides, hafnium oxides and oxynitrides, zirconium oxides and oxynitrides, magnesium oxides and oxynitrides, aluminum oxides and oxynitrides, titanium oxides and oxynitrides, tantalum oxides and oxynitrides, yttrium oxides and oxynitrides, and a combination thereof.

13. The method of claim 10, wherein the step of forming a first metal oxide gate capping layer and the step of forming a second metal oxide gate capping layer comprise forming a first metal oxide gate capping layer and forming a second metal oxide gate capping layer having different compositions.

14. The method of claim 10, wherein the step of forming a second metal oxide gate capping layer comprises forming a second metal oxide gate capping layer comprising a material selected from a group consisting of lanthanum oxides and oxynitrides, hafnium oxides and oxynitrides, zirconium oxides and oxynitrides, magnesium oxides and oxynitrides, aluminum oxides and oxynitrides, titanium oxides and oxynitrides, tantalum oxides and oxynitrides, yttrium oxides and oxynitrides, and a combination thereof.

15. The method of claim 10, wherein the step of forming a first metal oxide gate capping layer comprises forming the first metal oxide gate capping layer having a thickness in a range of from about 0.1 nm to about 1 nm.

16. The method of claim 10, wherein the step of forming a first metal oxide gate capping layer and the step of forming a second metal oxide gate capping layer comprise forming a first metal oxide gate capping layer and forming a second metal oxide gate capping layer having the same composition.

17. The method of claim 10, wherein the step of forming a first metal gate electrode layer and the step of forming a second metal gate electrode layer comprise forming a first metal gate electrode layer and forming a second metal gate electrode layer each comprising a material selected from a group consisting of lanthanum (La) and lanthanum alloys, aluminum (Al) and aluminum alloys, magnesium (Mg) and magnesium alloys, titanium-based materials, tantalum-based materials, and tungsten nitride (WN), and wherein the first metal gate electrode layer comprises a composition different than the composition of the second metal gate electrode layer.

18. The method of claim 10, wherein the step of forming a first metal gate electrode layer and the step of forming a second metal gate electrode layer comprise forming a first metal gate electrode layer and forming a second metal gate electrode layer having the same composition.

19. A semiconductor device having a first gate stack overlying a semiconductor substrate, the first gate stack comprising:
a first silicon oxide insulator disposed overlying the semiconductor substrate;
a first metal oxide gate capping layer disposed overlying the first silicon oxide insulator; and
a first metal gate electrode layer disposed overlying the first metal oxide gate capping layer.
